(19) United States
(12) Patent Application Publication
(10) Pub. No.: US 2020/0367363 A1
(43) Pub. Date: Nov. 19, 2020

(54) SUBSTRATE CONNECTION STRUCTURE

(71) Applicant: SHARP KABUSHIKI KAISHA, Osaka (JP)

(72) Inventor: MASAKI NAKAYAMA, Osaka (JP)

(21) Appl. No.: 15/931,440

(22) Filed: May 13, 2020

Related U.S. Application Data
(60) Provisional application No. 62/849,712, filed on May 17, 2019.

(51) Int. Cl. H05K 1/18; H05K 1/02

(52) U.S. Cl. CPC H05K 1/189; H05K 1/0281

(57) ABSTRACT

A substrate connection structure includes a wiring substrate, a base having an insulating property, a first terminal portion, and a second. terminal portion, in which a plurality of first terminal portions are disposed side by side in a first array direction, and extend by being inclined relative to the first array direction so that extended lines of the first terminal portions in an extension direction cross at a first intersection, a plurality of second terminal portions are disposed side by side in a second array direction, and extend by being inclined relative to the second array direction so that extended lines of the second terminal portions in an extension direction cross at a second intersection, and a first intersection direction directed from a first. center position to the first intersection and a second intersection direction directed from a second center portion to the second intersection are forward directions.

### CROSS-REFERENCE TO RELATED APPLICATION

The present application claims priority from Provisional Application No. 62/849,712, the content to which is hereby incorporated by reference into this application.

### BACKGROUND OF THE INVENTION

### 1. Field of the Invention

The present invention relates to a substrate connection structure.

### 2. Description of the Related Art

Flexible substrates (FPC, Flexible Printed Circuits) having flexibility are conventionally known as a wiring substrate that connects two electronic components. A flexible substrate has a film shape and, for example, greatly expands and contracts due to heat and thus easily causes dimensional tolerance during manufacturing, for example, a dimension of a wiring interval is different from a design dimension. Thus, position correction is performed at a time of connection to an electronic component. As a substrate connection structure for appropriately performing the position correction, a technique described in PTL 1 is disclosed.

In a substrate connection structure described. in Japanese Unexamined Patent Application Publication No. 2015-204458, a plurality of pad portions (terminal portions) of a flexible substrate are arrayed side by side and a plurality of pad portions (terminal portions) of a display panel that are connected thereto are arrayed side by side each along a first direction axis in a truncated chevron shape (radially). With the array in such a form, position correction is able to be appropriately performed by moving any one of the display panel and the flexible substrate along a second direction axis orthogonal to the first direct ion axis.

However, when any one of the display panel and the flexible substrate is moved for the position correction, a dimension from the display panel to the flexible substrate varies depending on a correction amount, so that tolerance of the dimension is newly caused.

### SUMMARY OF THE INVENTION

The invention is completed on the basis of circumstances described above and aims to suppress dimensional tolerance caused by position correction.

(1) An embodiment of the invention is a substrate connection structure by which a wiring substrate that connects a first electronic component and a second electronic component is connected to the first electronic component and the second electronic component, in which the first electronic component includes a first electronic component terminal portion connected to the wiring substrate, the second electronic component includes a second electronic component terminal portion connected to the wiring substrate, the wiring substrate includes a base having an insulating property, a first terminal portion that is provided on the base, connected to the first electronic component terminal portion, and has an elongated shape, and a second terminal portion that is provided on the base, connected to the second electronic component terminal portion, and has an elongated shape, a plurality of first terminal portions are disposed side by side in a first array direction, and extend by being inclined relative to the first array direction so that extended lines of the first terminal portions in an extension direction cross at a first intersection, a plurality of second terminal portions are disposed side by side in a second array direction, and extend by being inclined relative to the second array direction so that extended lines of the second terminal portions in an extension direction cross at a second intersection, and a first intersection direction directed from a first center position in array of the first terminal portions to the first intersection and a second intersection direction directed from a second center portion in array of the second terminal portions to the second intersection are forward directions.

(2) Moreover, an embodiment of the invention is the substrate connection structure in which a plurality of first electronic component terminal portions are disposed side by side in the first array direction and extend by being inclined relative to the first array direction so that extended lines of the first electronic component terminal portions in an extension direction cross at the first intersection, and a plurality of second electronic component terminal portions are disposed side by side in the second array direction and extend by being inclined relative to the second array direction so that extended lines of the second electronic component terminal portions in an extension direction cross at the second intersection, in addition to the configuration of (1) described above.

(3) Moreover, an embodiment. of the invention is the substrate connection structure in which the base has flexibility and the wiring substrate forms a flexible substrate, in addition to the configuration of (2) described above.

(4) Moreover, an embodiment of the invention is the substrate connection structure in which a plurality of wiring substrates are provided so as to extend across the first electronic component and the second electronic component, in addition to any one configuration of (1) to (3) described above.

(5) Moreover, an embodiment of the invention is the substrate connection structure in which first intersection directions of all the wiring substrates are forward directions, in addition to the configuration of (4) described above.

(6) Moreover, an embodiment of the invention is the substrate connection structure in which the wiring substrates include ones first intersection directions of which are reverse to each other, in addition to the configuration of (4) described above.

(7) Moreover, an embodiment. of the invention is the substrate connection structure in which the first terminal portion and the first electronic component terminal portion are connected and the second terminal portion and the second electronic component terminal portion are connected each via a conductive material composed of a thermosetting resin material, in addition to any one configuration of (1) to (6) described above.

(8) Moreover, an embodiment of the invention is the substrate connection structure in which the second electronic component is a driver mounting substrate and a driver is mounted on the driver mounting substrate, in addition to any one configuration of (1) to (7) described above.

(9) Moreover, an embodiment of the invention is the substrate connection structure in which the first electronic component is a display panel, in addition to any one configuration of (1) to (8) described above.

(10) Moreover, an embodiment of the invention is the substrate connection structure in which a plurality of wiring substrates are provided along an outer peripheral edge of the display panel, in addition to the configuration of (9) described above.

(11) Moreover, an embodiment of the invention is the substrate connection structure in which a plurality of second electronic components are connected to the display panel, in addition to the configuration of (9) or (10) described above.

### ADVANTAGEOUS EFFECTS OF INVENTION

According to the invention, dimensional tolerance caused by position correction is able to be suppressed.

### BRIEF DESCRIPTION OF DRAWINGS

FIG. 1 is a sectional view of a liquid crystal display apparatus using a substrate connection structure according to Embodiment 1.

FIG. 2 is a plan view illustrating the substrate connection structure in a state where a first flexible substrate and a second flexible substrate are bent.

FIG. 3 is an enlarged view of a vicinity of the first flexible substrate in FIG. 2.

FIG. 4 is a sectional view taken along a line IV-IV in FIG. 3.

FIG. 5 is a plan view illustrating a driver mounting substrate terminal portion and a liquid crystal panel terminal portion.

FIG. 6 is an enlarged view of a frame part VI in FIG. 5.

FIG. 7 is an enlarged plan view of the st flexible substrate and a liquid crystal panel before position correction.

FIG. 8 is an enlarged view of a frame part VIII in FIG. 5.

FIG. 9 is an enlarged plan view of the first flexible substrate and the driver mounting substrate before position correction.

FIG. 10 is a plan view illustrating a substrate connection structure according to Comparative example 1.

FIG. 11 is a plan view illustrating a substrate connection structure according to Embodiment 2.

FIG. 12 is a plan view illustrating a substrate connection structure according to Embodiment 3.

FIG. 13 is a plan view illustrating a substrate connection structure according to Embodiment 4.

FIG. 14 is a plan view illustrating a substrate connection structure according to Embodiment 5.

### DETAILED DESCRIPTION OF THE INVENTION

### Embodiment 1

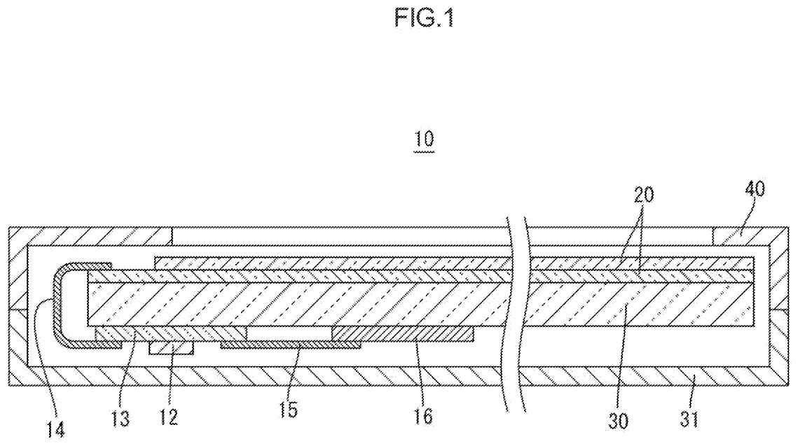

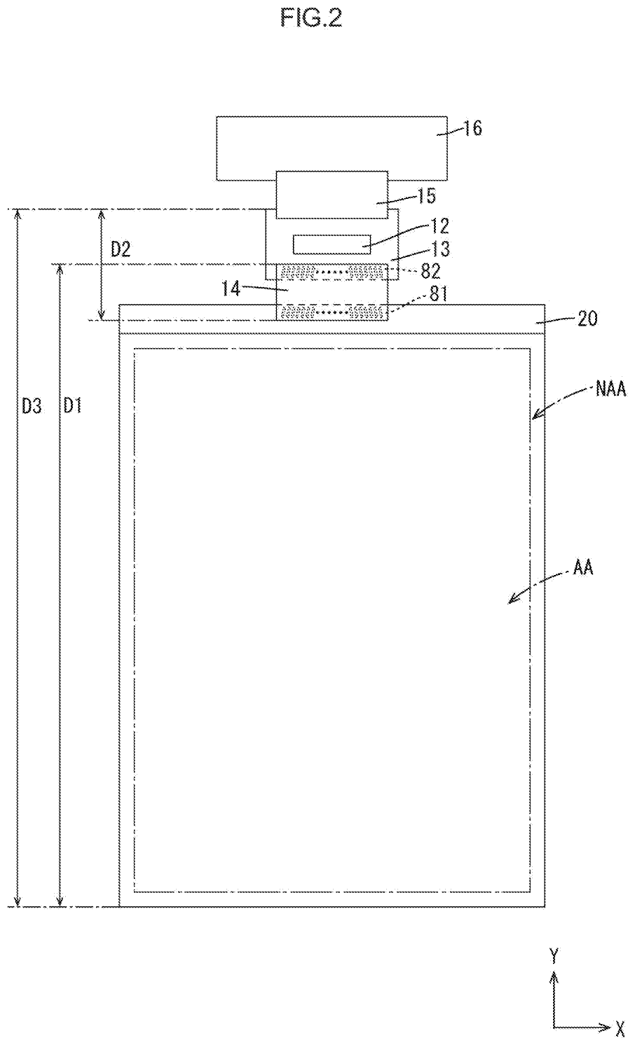

Embodiment 1 will be described with reference to FIGS. 1 to 9. In the present embodiment, a liquid crystal display apparatus 10 (an example of a display apparatus) using a substrate connection structure is exemplified. Note that, an X-axis, a Y-axis, and a Z-axis are illustrated at a part of each of FIGS. 2 to 14 and X-axis, Y-axis, and Z-axis directions represent directions common in the drawings. Moreover, in the following description, a liquid crystal panel 20 side and a backlight device 30 side in the Z-axis direction are respectively defined as a front side and a hack side.

As illustrated in FIG. 1, the liquid crystal display apparatus 10 includes the liquid. crystal panel 20 (an example of a display panel) (an example of a first electronic component) that displays an image and the backlight device 30 (an example of a lighting device) that is arranged on a back side of the liquid crystal panel 20 and emits light, and the liquid crystal panel 20 and the backlight device 30 are integrally held by a bezel 40 (support member), a chassis 31 (storage member), and the like. The liquid crystal panel 20 is configured so that a liquid crystal layer that includes liquid crystal molecules whose optical characteristics change when an electric field is applied is held between a pair of glass substrates. As illustrated in FIG. 2, the liquid crystal panel 20 has a longitudinally elongated quadrangular (rectangular) shape as a whole and has an inner surface sectioned into a display region (active area) AA in which an image is able to be displayed and which is disposed on a central side, and a non -display region (non-active area) NAA which has a rim shape (frame shape) in plan view in a form of surrounding the display region AA.

A driver 12 as an electronic component, such as an IC, which controls drive of the liquid crystal. panel 20 is mounted on a driver mounting substrate 13 (an example of a second electronic component), and the driver mounting substrate 13 is connected to the liquid crystal panel 20 via a first flexible substrate 14 that is a wiring substrate having flexibility. Moreover, the driver mounting substrate 13 is connected to a. control substrate 16, such as a system LSI, which supplies image data needed for image display and various types of control signals from outside, via a second flexible substrate 15. The st and second flexible substrates 14 and 15 respectively include bases 14S and 15S composed of a synthetic resin material, such as polyimide resin, which has an insulating property and flexibility, and a metal foil which is made of copper or the like and on which multiple wiring patterns are formed is layered on each of the bases. Thus, the first and second flexible substrates 14 and 15 are able to be easily bent or folded and are able to be mounted on the liquid crystal display apparatus 10 in a folded state as in the first flexible substrate 14 in FIG. 1.

A signal from the control substrate 16 is supplied via the second flexible substrate 15 to the driver 12 mounted on the driver mounting substrate 13, and a signal from the driver 12 is supplied via the first flexible substrate 14 to the liquid crystal panel 20. When the driver 12 is mounted on the driver mounting substrate 13 while such a wiring structure is provided, it is not necessary to secure a space where the driver 12 is provided in the non-display region NAA of the liquid crystal panel 20, so that a picture-frame of the liquid crystal display apparatus 10 is able to be narrowed by saving the space of the non-display region NAA. Moreover, in a case where it is assumed that the driver 12 is directly mounted on the liquid crystal panel 20, when warping is caused in the driver 12 due to heat that acts during the mounting, a glass substrate of the liquid crystal panel 20 is distorted by following the warping, resulting that display unevenness may occur in the liquid crystal panel 20, but the occurrence of such display unevenness is avoided by the present embodiment.

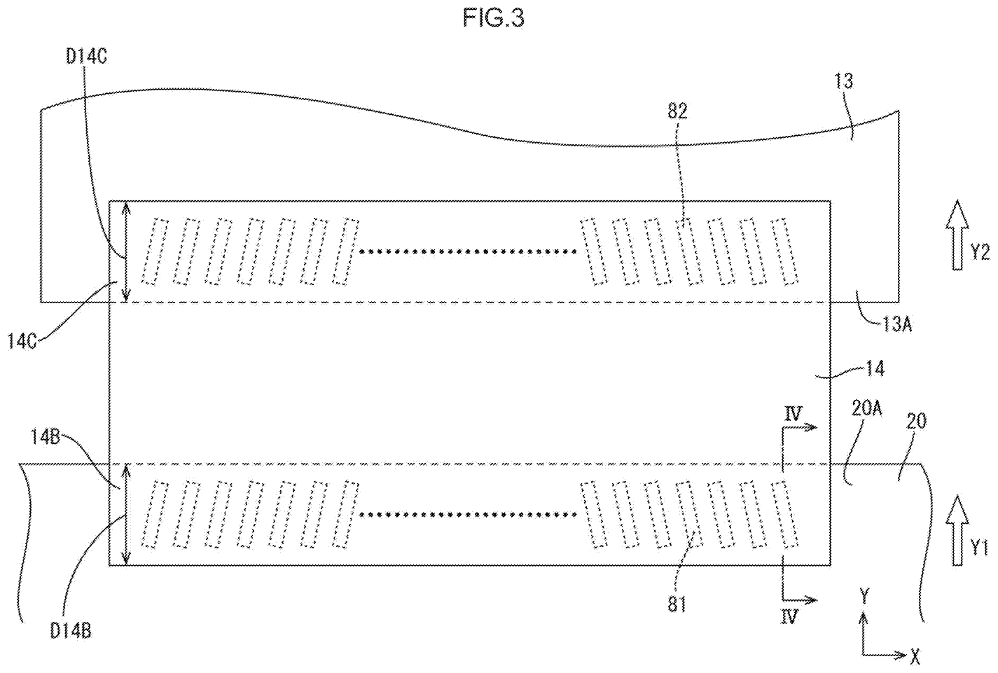

The first flexible substrate 14 has a laterally elongated quadrangular shape as illustrated in FIG. 3 and is provided so as to connect the liquid crystal panel 20 and the driver mounting substrate 13 while extending across them. The first flexible substrate 14 has, in a surface thereof, a liquid crystal panel connection region 14B overlapped with the liquid crystal panel 20 and a driver mounting substrate connection region 14C overlapped with the driver mounting substrate 13. in a back surface 14A of the first flexible substrate 14, a first terminal portion 81 for connection to the liquid crystal panel 20 is provided in the liquid crystal panel connection region 14B and a second terminal portion 82 for connection to the driver mounting substrate 13 is provided in the driver mounting substrate connection region 14C. Each of the first and second terminal portions 81 and 82 is composed of a metal material having excellent conductivity, such as copper.

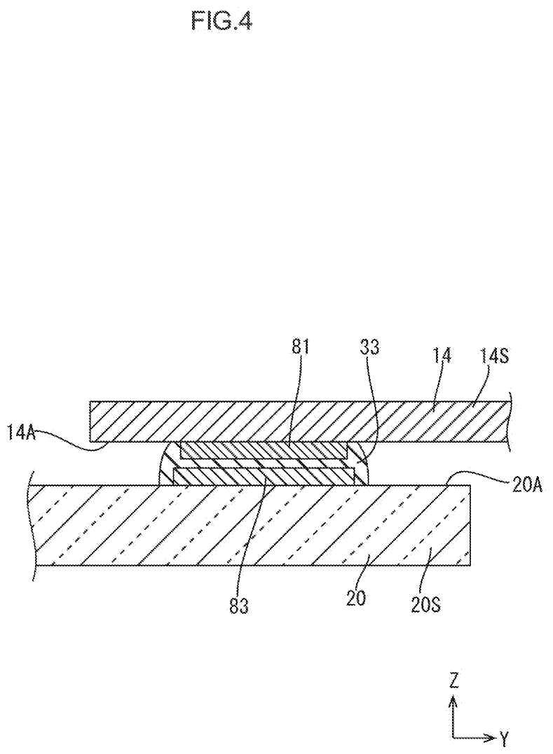

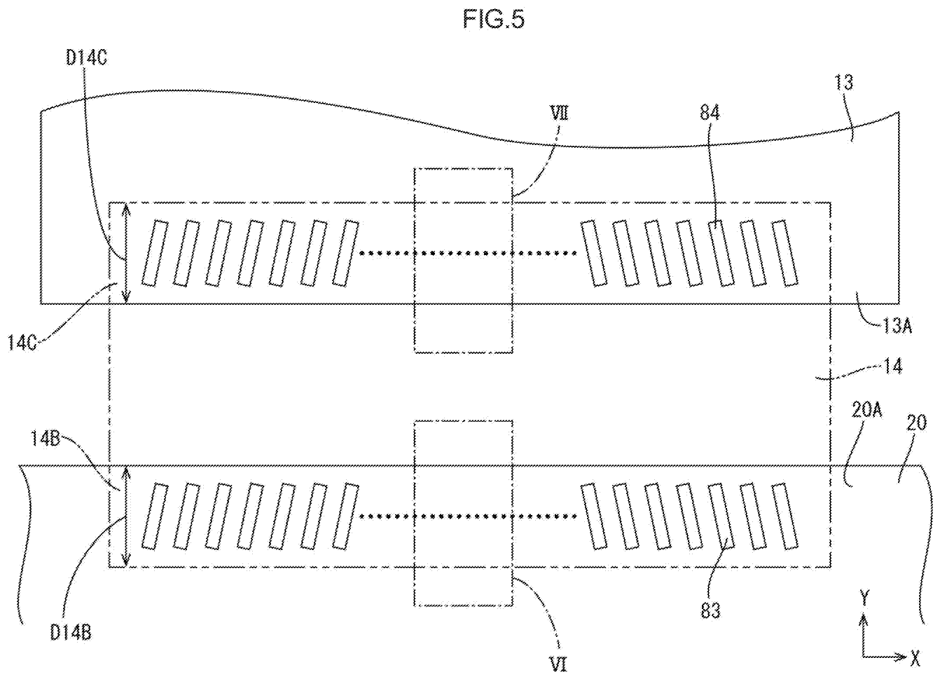

On a front surface 20A of the liquid crystal panel 20, as illustrated in FIGS. 4 and 5, a liquid crystal panel terminal portion 83 (an example of a first electronic component terminal portion) is provided so as to be overlapped with the first terminal portion 81 in plan view. Moreover, on a front surface 13A of the driver mounting substrate 13, a driver mounting substrate terminal portion 84 (an example of a second electronic component terminal portion) is provided so as to be overlapped with the second terminal portion 82 in plan view. Each of the liquid crystal panel terminal portion 83 and the driver mounting substrate terminal portion 84 is composed of a metal material having excellent conductivity, such as copper. As illustrated in FIG. 4, the first terminal portion 81 and the liquid crystal panel terminal portion 83 are connected by a conductive material 33, and, similarly, the second terminal portion 82 and the driver mounting substrate terminal portion 84 are connected by the conductive material 33. The conductive material 33 is composed of, for example, a thermosetting resin material in which conductive particles are dispersed and compounded.

A plurality of first terminal portions 81 are arrayed side by side and a plurality of liquid crystal panel terminal portions 83 connected thereto are arrayed side by side each along a first. array direction (X-axis direction) as illustrated in FIGS. 3 and 5. Each of the first terminal portions 81 and each of the liquid crystal panel terminal portions 83 have a long and narrow shape (elongated shape), and are inclined so that longitudinal directions (extension direction) of the first terminal portion 81 and the liquid. crystal panel terminal portion 83 cross the st array direction (X-axis direction) and a direction (Y-axis direction) vertical to the first. array direction. Similarly, a plurality of second terminal portions 82 are arrayed side by side and a plurality of driver mounting substrate terminal portions 84 connected thereto are arrayed side by side each along the X-axis direction as illustrated in FIGS. 3 and 5. Each of the second terminal portions 82 and each of the driver mounting substrate terminal portions 84 have a long and narrow shape (elongated shape), and are inclined so that longitudinal directions (extension direction) of the second terminal portion 82 and the driver mounting substrate terminal portion 84 cross the second array direction (X-axis direction) and a direction (Y-axis direction) vertical to the second array direction.

When the first terminal portions 81, the second. terminal portions 82, the liquid crystal panel terminal portions 83, and the driver mounting substrate terminal portions 84 are disposed in this manner, as compared to a case where it is assumed that they are disposed so that an extension direction thereof is parallel to the Y-axis direction, lengths D14B and D14C of the liquid crystal panel connection region 14B and the driver mounting substrate connection region 14C in the Y-axis direction are able to be shortened and spaces for the regions are able to be saved. Moreover, as described below, position correction of the first terminal portions 81 and the liquid crystal panel terminal portions 83 and position correction of the second terminal portions 82 and the driver mounting substrate terminal portions 84 are able to be easily performed.

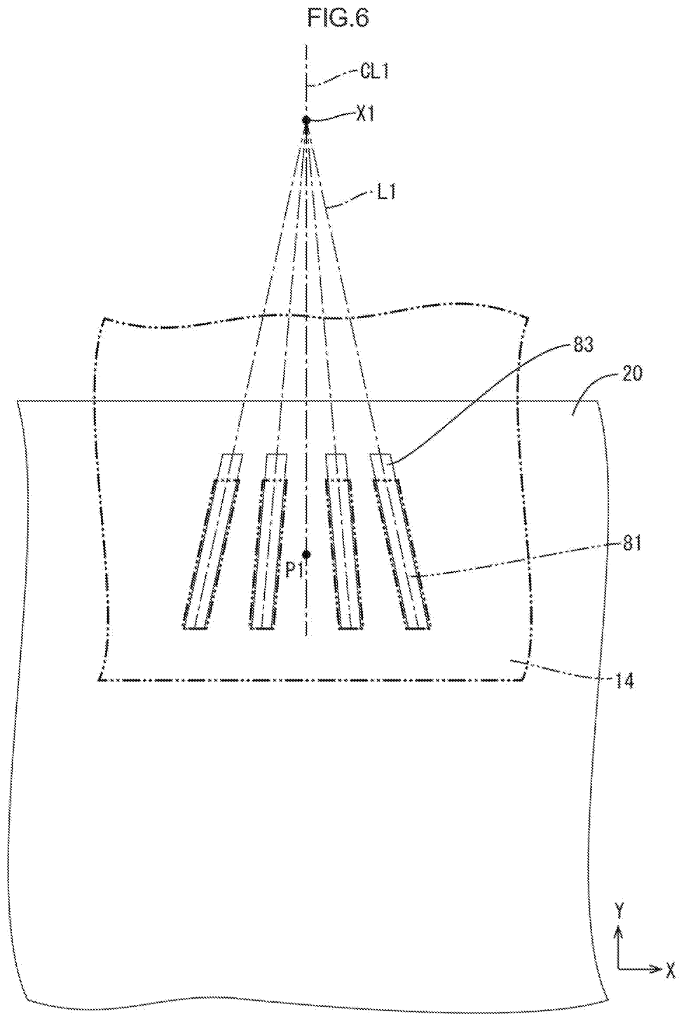

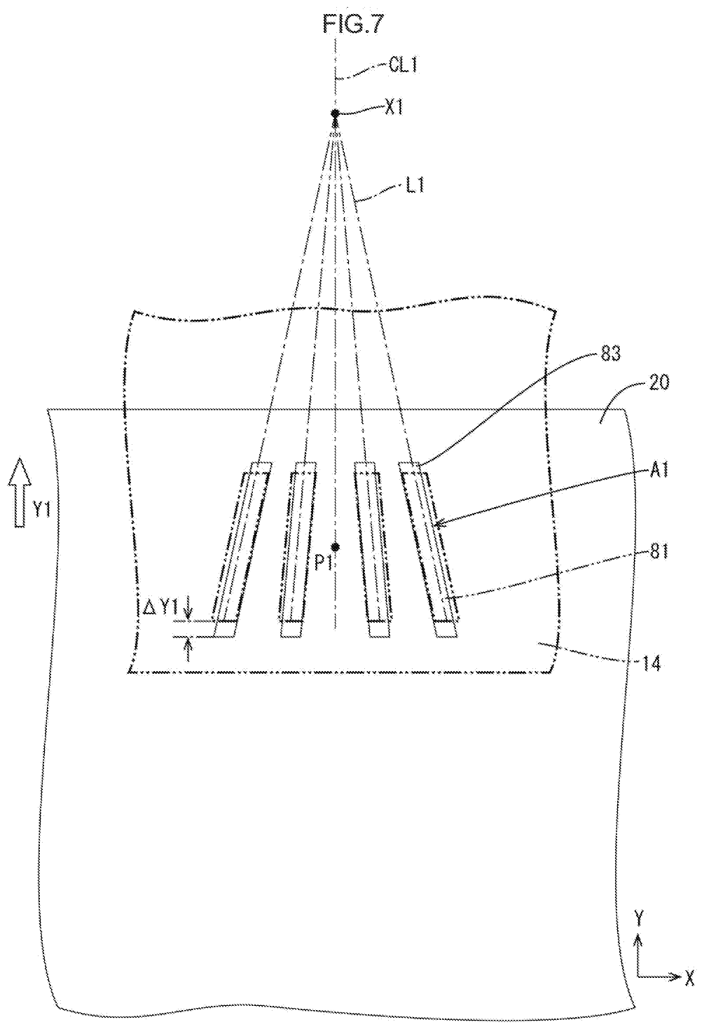

As illustrated in FIGS. 6 and 7, the first terminal portions 81 and the liquid crystal panel terminal portions 83 are inclined so that extended lines L1 of the first terminal portions 81 and the liquid crystal panel terminal portions 83 in the extension direction cross at a first intersection X1. In other words, the first terminal portions 81 and the liquid crystal panel terminal portions 83 are provided on the extended lines L1 that radially extend from the first intersection X1. The first intersection Xi is positioned on a first center line CL1 (Y-axis direction) that passes through a first center position P1 in the array of the first terminal portions 81 and is orthogonal to the array direction (X-axis direction) of the first terminal portions 81, and the first terminal portions 81 and the liquid crystal panel terminal portions 83 are provided so as to be line-symmetrical with respect to the first center line CL1. Note that, in FIGS. 6 and 7, for convenience of illustration, the first flexible substrate 14 and the first terminal portions 81 are indicated by two-dot chain lines and the liquid crystal panel 20 and the liquid crystal panel terminal portions 83 are indicated by solid lines.

Next, position correction of the first terminal portions 81 and the liquid crystal panel terminal portions 83 will be specifically described. As an example, considered is a case where manufacturing is performed in a state where a distance between adjacent first terminal portions 81 is longer than a design value and dimensional tolerance is caused as illustrated in FIG. 7. In this case, in an X-Y plane of a first terminal portion 81, a non-overlapping region A1 where the first terminal portion 81 is not overlapped with a liquid crystal panel terminal portion 83 in plan view is generated. When the non-overlapping region Al increases, connection resistance between the first terminal portion 81 and the liquid crystal panel terminal portion 83 increases or connection failure occurs.

Thus, when the liquid crystal panel 20 is moved along the first center line CL1 by AY1 in a +Y-axis direction (from a lower side to an upper side in FIG. 7), the non-overlapping region A1 is reduced. In other words, by moving the liquid crystal panel 20 by ΔY1 in a first intersection direction (indicated by an arrow Y1 in FIG. 7) directed from the first center position P1 to the first intersection X1, the non-overlapping region A1 is reduced. As a result, positional deviation between the first terminal portion 81 and the liquid crystal panel terminal portion 83 is able to be eliminated to bring a state where position correction is performed as in FIG. 6.

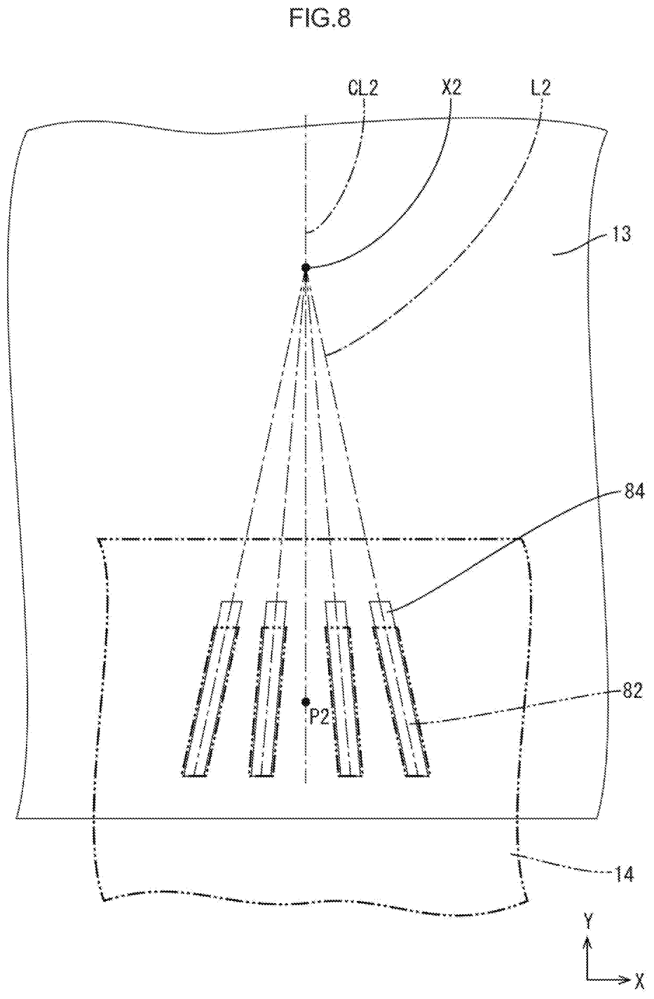

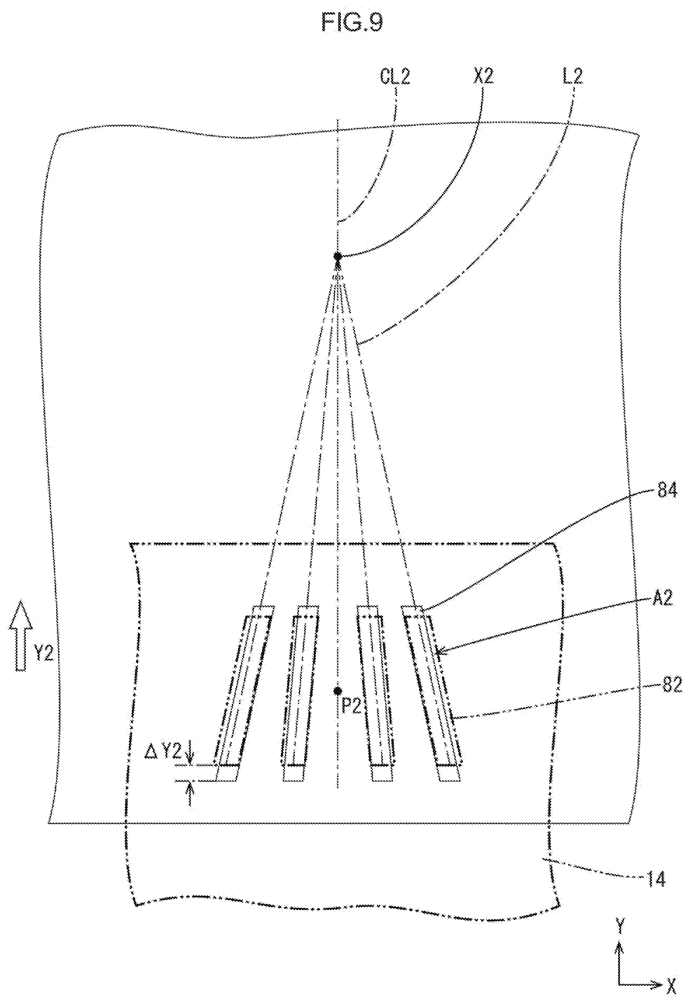

Similarly, as illustrated in FIGS. 8 and 9, the second terminal portions 82 and the driver mounting substrate terminal portions 84 are inclined so that extended lines L2 of the second terminal portions 82 and the driver mounting substrate terminal portions 84 in the extension direction cross at a second intersection X2. In other words, the second terminal portions 82 and the driver mounting substrate terminal portions 84 are provided on the extended lines L2 that .radially extend from the second intersection X2. The second intersection X2 is positioned on a second center line CL2 (Y-axis direction) that passes through a second center position P2 in the array of the second terminal portions 82 and is orthogonal to the array direction (X-axis direction) of the second terminal portions 82, and the second terminal portions 82 and the driver mounting substrate terminal portions 84 are provided so as to be line-symmetrical with respect to the second center line CL2.

When the second terminal portions 82 and the driver mounting substrate terminal portions 84 are disposed on the extended lines L2 that radially extend in this manner, similarly to the aforementioned position correction between the first terminal portions 81 and the liquid crystal panel 20, when the driver mounting substrate 13 is moved along the second center line CL2 by ΔY2 in the +Y-axis direction, a non-overlapping region A2 is reduced. That is, by moving the driver mounting substrate 13 by ΔY2 in a second intersection direction (indicated by an arrow Y2 in FIG. 9) directed from the second center position P2 to the second intersection X2, the non-overlapping region A2 is reduced. As a result, positional deviation between the second terminal portions 82 and the driver mounting substrate terminal portions 84 is able to be eliminated to bring a state where position correction is performed as in FIG. 8.

Since the liquid crystal panel 20 is moved in the +Y-axis direction by ΔY1 by the aforementioned position correction between the first terminal portions 81 and the liquid crystal panel terminal portions 83, a dimension D1 (FIG. 2) from a lower end of the liquid crystal panel 20 to an upper end of the first flexible substrate 14 is reduced. by a correction amount AY1. Moreover, since the driver mounting substrate 13 is moved in the +Y-axis direction by ΔY2 by the position correction of the driver mounting substrate 13 with respect to the second terminal portions 82, a dimension D2 (FIG. 2) from an upper end of the driver mounting substrate 13 to a lower end of the first flexible substrate 14 is increased by a correction amountΔAY2. As a result, by the position correction, a dimension D3 (FIG. 2) from the upper end of the driver mounting substrate 13 to the lower end of the liquid crystal panel 20 changes by a difference ΔY2−ΔY1 between the correction amount ΔY1 and the correction amount ΔY2 that are described above. In a case of ΔY1=ΔY2, a change amount of the dimension D3 is zero. Thus, according to the present embodiment, at a time of the position correction for the first flexible substrate 14, since a moving direction (first intersection direction Y1) of the liquid crystal panel 20 and a moving direction (second intersection direction Y2) of the driver mounting substrate 13 are forward directions, the liquid crystal panel 20 and the driver mounting substrate 13 move in the same direction, so that the dimension D3 from the liquid crystal panel 20 to the driver mounting substrate 13 has the change amount (dimensional tolerance) suppressed to be small and is difficult to change before and after the position correction.

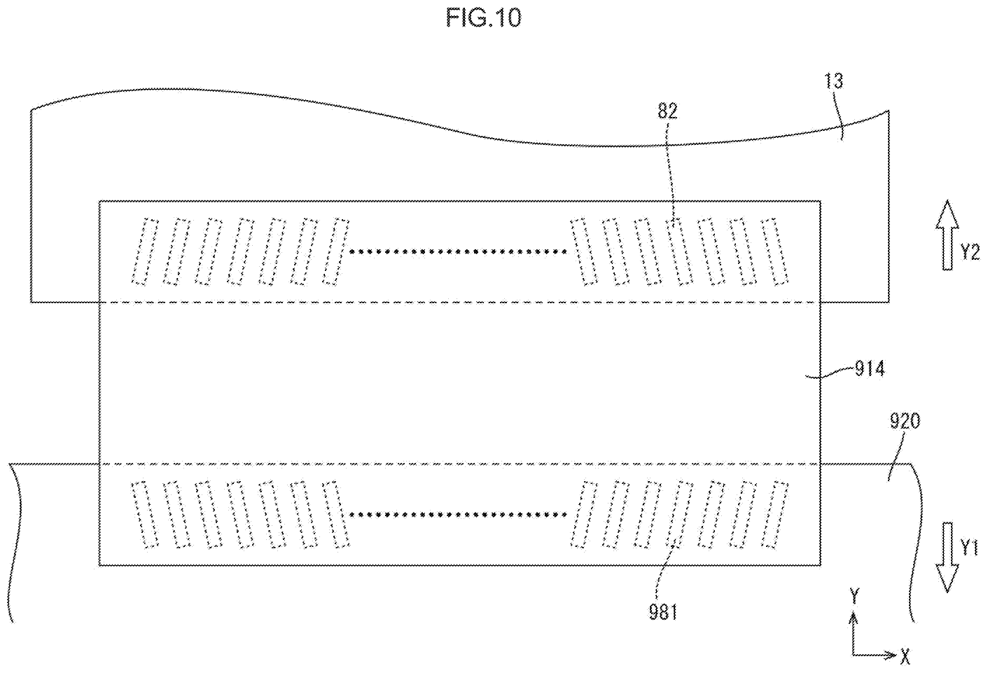

On the other hand, in a case where it is assumed that the first intersection. direction Y1 and the second intersection direction Y2 are reverse to each other as in a substrate connection structure indicated in Comparative example 1 in FIG. 10, a direction in which a liquid crystal panel 920 is moved and a direction in which the driver mounting substrate 13 is moved are opposite at a time of position correction. When the liquid crystal panel 920 and the driver mounting substrate 13 move in the opposite directions, a dimension D3 from the liquid crystal panel 920 to the driver mounting substrate 13 changes by a sum ΔY1+ΔY2 of a correction amount ΔY1 of the liquid crystal panel 920 and a correction. amount ΔY2 of the driver mounting substrate 13, so that. a change amount (dimensional tolerance) is increased. In particular, in a case of ΔY1=ΔY2, the dimensional tolerance of the dimension D3 is twice ΔY1 and is larger than that in the aforementioned case (the dimensional tolerance of the dimension 03 is zero) of Embodiment 1.

As described above, the substrate connection structure according to the present embodiment is the substrate connection structure by which the first flexible substrate 14 that connects the liquid crystal panel 20 and the driver mounting substrate 13 is connected to the liquid crystal panel 20 and the driver mounting substrate 13, in which the liquid crystal panel 20 includes the liquid crystal panel terminal portion 83 connected to the first flexible substrate 14, the driver mounting substrate 13 includes the driver mounting substrate terminal portion 84 connected to the first flexible substrate 14, the first flexible substrate 14 includes the base 14S having the insulating property, the first terminal portion 81 that is provided on the base 14S and connected to the liquid crystal terminal portion 83, and the second terminal portion 82 that is provided on the base 14S and connected to the driver mounting substrate terminal portion 84, a plurality of first terminal portions 81 are disposed side by side in the first array direction, and extend by being inclined relative to the first array direction so that the extended lines L1 of the first terminal portions 81 in the extension direction cross at the first intersection X1, a plurality of second terminal portions 82 are disposed side by side in the second array direction, and extend by being inclined relative to the second array direction so that the extended lines L2 of the second terminal portions 82 in the extension direction cross at the second intersection X2, and the first intersection direction Y1 directed from the first center position P1 in. the array of the first terminal portions 81 to the first intersection X1 and the second intersection direction Y2 directed from the second center portion P2 in the array of the second terminal portions 82 to the second intersection X2 are forward directions.

Thereby, when the position correction of the first terminal portions 81 and the liquid crystal panel terminal portions 83 is performed, relative positions thereof are corrected by moving the liquid crystal panel 20 in the first intersection direction Y1. Similarly, when the position direction of the second terminal portions 82 and the driver mounting substrate terminal portions 84 is performed, relative positions thereof are corrected by moving the driver mounting substrate 13 in the second intersection direction Y2. Therefore, when the first intersection direction Y1 and the second intersection direction Y2 are set to be forward. directions (so as to be directed in the same direction), the direction in which the liquid crystal panel 20 is moved and the direction in which the driver mounting substrate 13 is moved coincide at a time of the position correction. When the liquid crystal panel 20 and the driver mounting substrate 13 move in the same direction, the dimension D3 from the liquid crystal panel 20 to the driver mounting substrate 13 is difficult to change before and after the position correction. As a result, tolerance of the dimension caused by the position correction is able to be suppressed.

Moreover, a plurality of liquid crystal panel terminal portions 83 are disposed side by side in the first array direction and extend by being inclined relative to the first array direction so that the extended lines of the liquid crystal panel terminal portions 83 in the extension direction cross at the first intersection X1, and a plurality of driver mounting substrate terminal portions 84 are disposed side by side in the second array direction and extend by being inclined relative to the second array direction so that the extended lines of the driver mounting substrate terminal portions 84 in the extension direction cross at the second intersection X2.

Thereby, the liquid. crystal panel terminal portions 83 and the first terminal portions 81 are matched in an array form and the driver mounting substrate terminal portions 84 and the second terminal portions 82 are matched in an array form, so that overlapping regions in connected parts increase. As a result, the position correction is easily performed.

### Embodiment 2

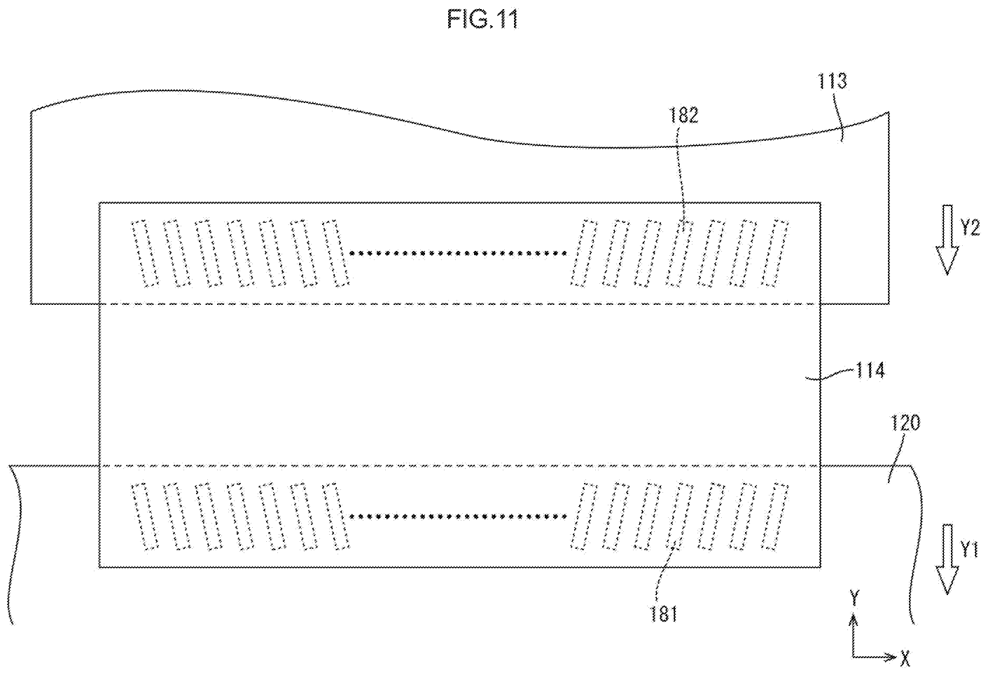

A substrate connection structure according to Embodiment 2 of the invention will be described with. reference to FIG. 11. In Embodiment 2, both of the first intersection direction Y1 and the second intersection direction Y2 are −Y-axis directions. Note that, redundant description for a configuration, an action, and an effect similar to those of Embodiment 1 described above will be omitted.

Also in the present embodiment, similarly to Embodiment 1, a direction in which a liquid. crystal panel 120 is moved and a direction in which a driver mounting substrate 113 is moved during position correction are forward directions and coincide with each other. Thus, dimensional tolerance of a dimension D3 from the liquid crystal panel 120 to the driver mounting substrate 113 is reduced by a difference ΔY1−ΔY2 between a correction. amount ΔY1 of the liquid crystal panel 120 and a correction amount ΔY2 of the driver mounting substrate 113. In particular, in a case of ΔY1=ΔY2, the dimensional tolerance of the dimension D3 is able to be made zero.

### Embodiment 3

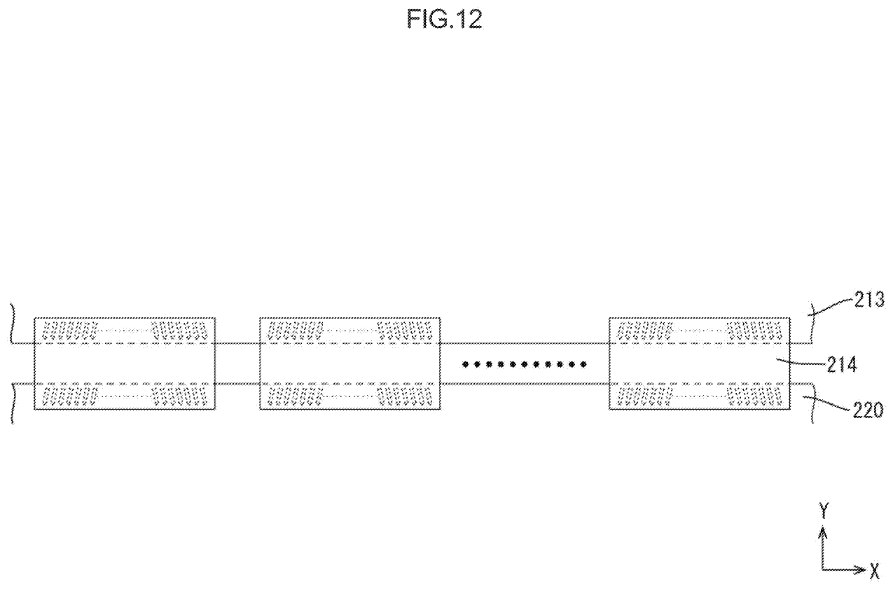

A substrate connection structure according to Embodiment 3 of the invention will be described with reference to FIG. 12. In Embodiment 3, a plurality of first flexible substrates 214 are provided so as to extend across a liquid crystal panel 220 and a driver mounting substrate 213. Note that, redundant description for a configuration, an action, and an effect similar to those of Embodiment 1 and Embodiment 2 described. above will be omitted.

A substrate connection structure of each of the plurality of first flexible substrates 214 has a similar configuration to that of the substrate connection structure of the first flexible substrate 14 of Embodiment 1. This is suitable for connecting the liquid crystal panel 220 and the driver mounting substrate 213 in a case where both of them have a large size. Note that, the number of drivers 12 mounted on the driver mounting substrate 213 and the number of second flexible substrates 15 connected to the driver mounting substrate 213 may not. match the number of first flexible substrates 214.

### Embodiment 4

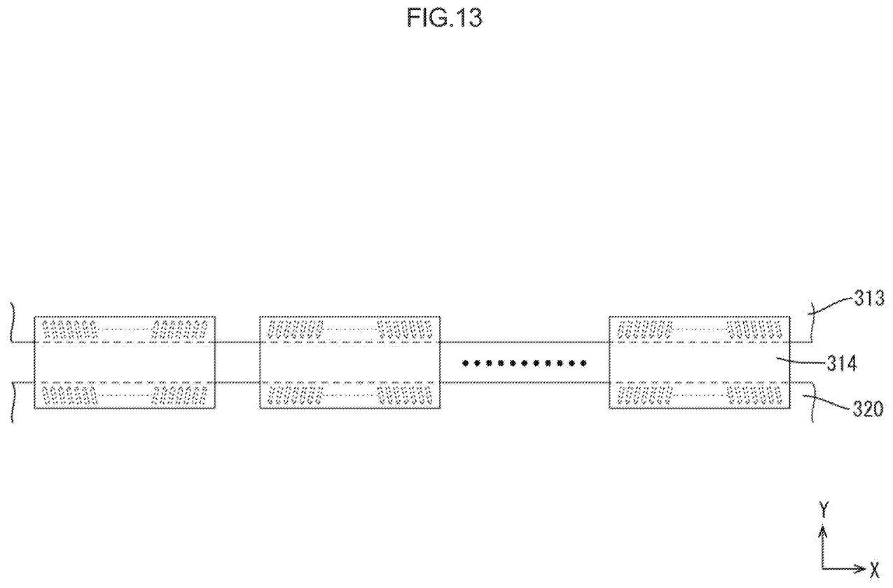

A substrate connection structure according to Embodiment 4 of the invention will be described with reference to FIG. 13. In Embodiment 4, a plurality of first flexible substrates 314 are provided so as to extend across a liquid crystal panel 320 and. a driver mounting substrate 313 and a substrate connection structure of each of the first flexible substrates 314 has a similar configuration to that of the substrate connection structure of Embodiment 1 or Embodiment 2. Note that, redundant description for a configuration, an action, and an effect similar to those of Embodiment 1 to Embodiment 3 described above will be omitted.

This is suitable for connecting the liquid crystal panel 320 and the driver mounting substrate 313 in a case where both of them have a large size. Note that, the number of drivers 12 mounted on the driver mounting substrate 313 and the number of second flexible substrates 15 connected to the driver mounting substrate 313 may not match the number of first flexible substrates 314.

### Embodiment 5

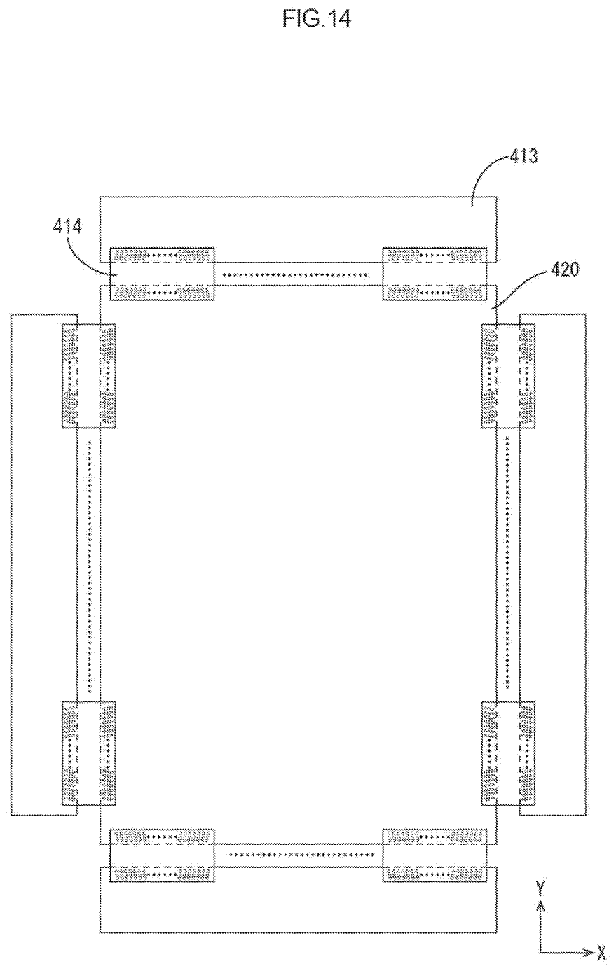

A substrate connection structure according to Embodiment 5 of the invention will be described with reference to FIG. 14. In Embodiment 5, a plurality of first flexible substrates 414 are provided along an outer peripheral edge of a liquid crystal panel 420. Note that, redundant description for a configuration, an action, and an effect similar to those of Embodiment 1 to Embodiment 4 described above will be omitted.

The liquid crystal panel 420 has a rectangular shape, a plurality of first flexible substrates 414 are provided in each of four sides that constitute the outer peripheral edge of the liquid crystal panel 420. A substrate connection structure of each of the first flexible substrates 414 in each of the sides has a similar configuration to that of Embodiment 3 or Embodiment 4. This is suitable for connecting the liquid crystal panel 420 and the driver mounting substrate 413 in a case where the liquid crystal panel 420 and the driver mounting substrate 413 have a large size and multiple wiring systems are provided so as to surround the outer peripheral edge of the liquid crystal panel 420. Note that, though FIG. 14 indicates an example in which the first flexible substrates 414 are provided in each of four sides, a first flexible substrate 414 may not be provided in a part of the sides. Moreover, the number of drivers 12 mounted on the driver mounting substrate 413 and the number of second flexible substrates 15 connected to the driver mounting substrate 413 may not match the number of first flexible substrates 414.

### Other Embodiments

The invention is not limited to the embodiments described with reference to the aforementioned description and drawings. For example, the following embodiments are also included in a technical scope of the invention.

(1) Though Embodiment 1 described above indicates, as an example of position correction, a case where manufacturing is performed in a state where a distance between adjacent first terminal portions and a distance between adjacent second terminal portions are larger than respective design values and dimensional tolerance is caused, application is allowed also in a case where manufacturing is performed in a state where a distance is smaller than a design value and dimensional tolerance is caused.

(2) Though Embodiment 1 described above indicates, as an example of position correction, a case where dimensional tolerance is caused in the first terminal portions and the second terminal portions, application is allowed also in a case where dimensional tolerance is caused in the first electronic component terminal portions and the second electronic component terminal portions. Further, application is allowed also in a case where dimensional tolerance is caused in all of them.

(3) Though Embodiment 1 described. above indicates an example in which there are one first intersection and one second intersection, a plurality of first intersections may be dispersed on the first center line and a plurality of second intersections may be dispersed on the second center line.

(4) Though Embodiment 1 described above exemplifies position correction of the first flexible substrate, application to the second flexible substrate is also allowed.

(5) Though Embodiment 1 to Embodiment 5 described above exemplify the display panel as the first electronic component and the driver mounting substrate as the second electronic component, application to other electronic components is also allowed.

(6) Though Embodiment 1 to Embodiment 5 described above exemplify a case where the liquid crystal panel has a rectangular shape, the liquid crystal panel may have a nonrectangular shape that includes a curve in the outer peripheral edge thereof.

(7) An electronic component such as an SOF (System On Film) may he mounted on the wiring substrate in Embodiment 1 to Embodiment 5 described above.

### REFERENCE SIGNS LIST

12 . . . driver, 13, 113, 213, 313, 413 . . . driver mounting substrate (second electronic component), 14, 114, 214, 314, 414 . . . first flexible substrate (wiring substrate), 14S . . . base, 15 . . . second flexible substrate (wiring^{.} substrate), 20, 120, 220, 320, 420 . . . liquid crystal panel (display panel, first. electronic component), 81 . . . first terminal portion, 82 . . . second terminal portion, 83 . . . liquid crystal panel terminal portion (first electronic component terminal portion), 84 . . . driver mounting substrate terminal portion (second electronic component terminal portion), P1 . . . first center position, P2 . . . second center position, X1 . . . first intersection, X2 . . . second intersection

What is claimed is

1. A substrate connection structure by which a wiring substrate that connects a first electronic component and a second electronic component is connected to the first electronic component and the second electronic component, wherein
the first electronic component includes a first electronic component terminal portion connected to the wiring substrate,
the second electronic component includes a second electronic component terminal portion connected to the wiring substrate,
the wiring substrate includes
a base having an insulating property,
a first terminal portion that is provided on the base, connected to the first electronic component terminal portion, and has an elongated shape, and
a second terminal portion that is provided on the base, connected to the second electronic component terminal portion, and has an elongated shape,
a plurality of st terminal portions are disposed side by side in a first array direction, and extend by being inclined relative to the first array direction so that extended lines of the first terminal portions in an extension direction cross at a first intersection,
a plurality of second. terminal portions are disposed side by side in a second array direction, and extend by being inclined relative to the second array direction so that extended lines of the second terminal portions in an extension direction cross at a second intersection, and
a first intersection direction directed from a first center position in array of the first terminal portions to the first intersection and a second intersection direction directed from a second center portion in array of the second terminal portions to the second intersection are forward directions.

2. The substrate connection structure according to claim 1, wherein
a plurality of first electronic component terminal portions ions are disposed side by side in the first array direction and extend by being inclined relative to the first array direction so that extended lines of the first electronic component terminal portions in an extension direction cross at the first intersection, and
a plurality of second electronic component terminal portions are disposed side by side in the second array direction and extend by being inclined relative to the second array direction so that extended lines of the second electronic component terminal portions in an extension direction cross at the second intersection.

3. The substrate connection structure according to claim 1, wherein the base has flexibility and the wiring substrate forms a flexible substrate.

4. The substrate connection structure according to claim 1, wherein a plurality of wiring substrates are provided so as to extend across the first electronic component and the second electronic component.

5. The substrate connection structure according to claim 4, wherein first intersection directions of all the wiring substrates are forward directions.

6. The substrate connection structure according to claim 4, wherein the wiring substrates include ones first intersection directions of which are reverse to each other.

7. The substrate connection structure according to claim 1, wherein the first terminal portion and the first electronic component terminal portion are connected and the second terminal portion and the second electronic component terminal portion are connected each via a conductive material composed of a thermosetting resin material.

8. The substrate connection structure according to claim 1, wherein the second electronic component is a driver mounting substrate and a driver is mounted on the driver mounting substrate.

9. The substrate connection structure according to claim 1, wherein the first electronic component is a display panel.

10. The substrate connection structure according to claim 9, wherein a plurality of wiring substrates are provided. along an outer peripheral edge of the display panel.

11. The substrate connection structure according to claim 10, wherein a plurality of second electronic components are connected to the display panel.
